(19) United States
(12) Patent Application Publication
(10) Pub. No.: US 2010/0139759 A1
(43) Pub. Date: Jun. 10, 2010

(54) OPTICAL DEVICE

(75) Inventor: Martin Aagesen, Hedehusene (DK)

Correspondence Address: KATTEN MUCHIN ROSENMAN LLP;(C/O PATENT ADMINISTRATOR), 2900 K STREET NW, SUITE 200, WASHINGTON, DC, 20007-5118, US

(73) Assignee: KOBENHAVNS UNIVERSITET, Copenhagen N (DK)

(21) Appl. No.: 12/517,512

(22) PCT Filed: Nov. 23, 2007
(86) PCT No.: PCT/DK2007/050175

§ 371 Date: Jan. 25, 2010

Related U.S. Application Data
(60) Provisional application No. 60/868,826, filed on Dec. 6, 2006.

(51) Int. Cl. H01L 31/0236; H01L 31/0368; H01L 33/00; H01L 21/20

(52) U.S. Cl. 136/256; 257/184; 257/465; 257/98; 438/488; 257/95; 257/E31.043; 257/E31.13; 257/E33.074; 257/E21.09; 257/E33.048

(57) ABSTRACT

The present invention relates to an optical device and to a method of fabricating the same. In embodiments, the invention relates to a photovoltaic device or solar cell. The optical device comprises a first electrode and a second electrode and an active element disposed between the first and second electrodes. The active element comprising a plurality of semiconducting structures extending in a lengthwise direction from the first electrode and being in contact with the first and second electrodes; the active element comprises an np-junction. For the semiconducting structures, at least a part of the structures is of a general plate or flake shape. In embodiments, the semiconducting structures have at least one characteristic dimension in the nanometer range.

### FIELD OF THE INVENTION

The present invention relates to an optical device and to a method of fabricating the same, moreover the invention relates to a photovoltaic device, a radiation detector and a light emitting device.

### BACKGROUND OF THE INVENTION

Solar energy has long been considered as a potential candidate of energy source to participate in the replacement of fossil fuels as the main energy source. However, widespread application of solar energy has to date been hampered by a somewhat limited efficiency of solar cells or photovoltaic cells, typically not much better than 20%, combined with a relative high production cost. Therefore, currently, solar cells are primarily used where conventionally generated energy is unavailable or where the cost of bringing conventional energy to the location more closely match the production cost of solar cells.

Current photovoltaic cells often employ thin layers of semiconductor material, e.g. crystalline silicon, gallium arsenide, or the like, incorporating an np-junction to convert photo-induced energy to direct current. While current photovoltaic cells steadily increase in efficiency, it is generally believed that the physical properties of these devices will limit the efficiency to around 30%.

Fine tuning of current types of photovoltaic cells is expensive in terms of development costs and moreover since the maximal achievable efficiency is believed to be limited, a direct improvement of current technology does not seem to be the proper strategy of providing a solar cell suitable for widespread use as an alternative to fossil fuels or other conventional energy sources. In a promising alternative, solutions have been proposed relating to photovoltaic cells based on microsized or nanosized semiconducting structures as the active element.

The U.S. Pat. No. 7,087,833 discloses a photovoltaic device that includes semiconductor nanostructures as at least a portion of a photoactive layer. A first and a second population of nanostructures which are made from different materials are provided, the two populations of nanostructures exhibit a type II band offset energy profile with respect to each other.

There is a need in the art for providing improved photovoltaic devices, and in general there is a need to provide improved optical devices, and in particular devices having a high efficiency-cost ratio would be advantageous.

### SUMMARY OF THE INVENTION

The present invention seeks to provide an improved optical device, and it may be seen as an object of the invention to provide a new optical device incorporating nanosized or microsized semiconducting structures in the, or as the, active element, and in particular such devices having a high efficiency-cost ratio.

It is a further object of the present invention to provide an alternative to the prior art.

Thus, the above described object and several other objects are intended to be obtained in a first aspect of the invention by providing an optical device comprising:
a first electrode;
a second electrode, the first or second electrode being at least partly transparent in a first wavelength range;
an active element disposed between the first and second electrodes; the active element comprising a plurality of semiconducting structures extending in a lengthwise direction from the first electrode and being in contact with the first and second electrodes; the active element comprises an np-junction; and
   wherein the semiconducting structures have heights in the lengthwise direction, and widths and thicknesses in orthogonal directions of the lengthwise direction, and where at least a part of the semiconducting structures is of a general plate shape where, at a section positioned at the lower half of at least the part the semiconducting structure, the width is substantially larger than the thickness.

The invention pertains to any type of optical device having an active element disposed between two electrodes. The specific type of optical device depends upon the mode of operation. In an embodiment, the optical device is a photovoltaic device or cell, including a radiation detector, other embodiments include light emitting devices, such as a LED.

The first and the second electrode may be made from any suitable electrical conducting material capable of providing an electrical connection from the outside to the active element.

The transparency of the first or the second electrode may be in the range of 50% to 100%, such as 75% to 90%. In principle, the higher the transparency the better, since it is optimal to maximize the intensity of the incoming radiation. The first wavelength range may be in a range from ultraviolet light to infrared light, such as a range from approximately 200 nm up to approximately 3.5 μm. The first wavelength range may span the entire range or be adapted to span one or more given sub-ranges. The first range may also be set up so that radiation in one or more specific ranges is blocked. The specific ranges provided may be tuned to the specific application of the device, or may be dictated by a specific design choice, including a specific material choice.

The functioning of the active element is at least to separate electron-hole pairs created in a process of interactions between the semiconducting structure and the incoming radiation, such as a photo-induced process. In an alternative embodiment of the active element, electron-hole pairs are injected into the semiconducting structure where they recombine resulting in the creation of radiation which is coupled out of the active element.

At least a plurality of the semiconducting structures is of a specific geometrical shape, the plurality of the semiconducting structures is of a general plate shape, the structures may be of a flake shape having a general pointing shape. In general reference is made to a plate form or shape as a structure being wider than thick, whereas reference to a flake shape is made as a specific type of plate having a general pointing shape. In general may also sub-populations of semiconducting structures of alternative shapes be present. Depending on the specific growth conditions may a number of alternative shape populations co-exists. Likewise also within a specific type of population, distributions of shapes and sizes may be present. In embodiments it may only be a part of the semiconducting structures which are of a general plate shape. In such embodiment, typically an inner structure is of a general plate shape, and regions have been grown from the inner plate shape structure.

The height of the semiconducting structures may be in the range of few hundred nanometers (nm) up to some micrometers (μm), typically 1 to 25 μm. The widths at the lower half of the semiconducting structures may be in the range of 100 nm to 2 μm, and the thickness may be in the range of 5 nm to 500 nm, typically 25 to 100 nm, such as 30 to 80 nm.

At the lower half of the semiconducting structure, or at least of the part of the semiconducting structure, the width is substantially larger than the thickness. In general the width-to-thickness ratio may be in the range of 1.5 to 500 or even more, such as in the range of 3 to 250, such as in the range of 5 to 100 such as in the range of 10 to 75, such as in the range of 25 to 50. The specific width to thickness ratio may depend upon the specific growth conditions applied. Typically a distribution of the width-to-thickness ratio is obtained, for such a distribution the centre of the distribution may be such that for the width-to-thickness ratio of the central part of the distribution, the width is substantially larger than the thickness.

The semiconducting structure may generally be referred to as a nanostructure having at least one region or characteristic dimension in the nanometer range, here at least the thickness of the semiconducting structure, or at least a part of the semiconducting structure, may be in the nanometer range.

The invention is particularly, but not exclusively, advantageous for providing an optical device with a high efficiency. The high efficiency is believed to be related to the geometry of the semiconducting structure. The dimension of the semiconducting structures give rise to a high probability of created electron-hole pairs are not recombined in the vicinity of the creation, instead they are separated at the electrodes.

By providing a device according to the invention, only a small quantity of expensive material is required. Moreover, due to the overall geometrical shape of the semiconducting structures, most of the incoming radiation are absorbed by a semiconducting structure, and not reflected by the surface, as a consequence an antireflective coating on the active element may be avoided. In embodiments, may an antireflective coating still be provided on the surface of the in-coupling electrode, i.e. on the surface of the first or second electrodes or both electrodes.

The first electrode may be of a substrate on which the semiconducting structures are grown or at least protruding from. The first electrode may be a group V/III semiconductor substrate, a group VI/II semiconductor substrate, a group IV semiconductor substrate or a substrate of an alloy thereof. In specific embodiments may the first electrode be a GaAs or Si substrate.

The first electrode may be a transparent conductor, such as a transparent conducting oxide (TCO), e.g. of indium tin oxide (ITO), a doped oxide such as SnO₂:F, ZnO:B, ZnO:Al, etc. The first electrode may also be of a conducting polymer material.

The first electrode may also be an insulator contacted with a conducting or semiconducting electrode, e.g. a glass substrate coated with a metal layer or a glass substrate coated with a semiconducting material.

The first electrode may be a layered structure, such as a structure having a having a first layer and at least a second layer.

The semiconducting structure may be substantially crystalline, such as substantially monocrystalline or polycrystalline. In general it is advantageous to provide semiconducting structures which are substantially crystalline at least over a length-scale of the structure. Since by providing a substantially crystalline structure only few or even no recombination centres may be present. A higher efficiency may thereby be provided.

The semiconducting structure may be of or at least include a group V/III semiconductor, a group VI/II semiconductor or a group IV semiconductor, or of any combination or alloy of such materials. In specific embodiments, the semiconducting structure may be of or at least include InAs, Si, CdSe, CdTe, InP, CdS, ZnS, ZnO, ZnSe, PbSe, PbS, ZnTe, HgTe, GaN, GaP, GaAs, GaSb, InSb, Ge, AlAs, AlSb or PbTe, or any compounds of such materials, including but not limited to ternary or quaternary compounds.

The semiconducting structure may have an absorbance in the visual range or in the infrared range, or both, of at least 70%, such as at least 80%, such as at least 90%, such as at least 95%, such as at least 98%.

The active element comprises an np-junction. The np-junction may be provided by the individual semiconducting structures, by providing semiconducting structures that comprise an n-region having an n-conductivity and a p-region having a p-conductivity, so that the interface between the regions is forming an np-junction. Such regions may be provided in a number of ways.

In an embodiment, semiconducting structures of a first conductivity are provided, the semiconducting structure is then either in connection with the growth or after the growth doped with a material providing a different second conductivity.

In an embodiment, semiconducting structures of n-conductivity or p-conductivity are provided and onto which a semiconductor material of n-conductivity or p-conductivity are provided, so that the semiconducting structure abuts a region having an n-conductivity or p-conductivity, thereby forming an np-junction in the interface.

In an embodiment, semiconducting structures of n-conductivity or p-conductivity are provided and onto which a semiconductor material of the same conductivity is provided, and onto this a semiconductor material of different conductivity is provided, so that the semiconducting structure comprises or supports a region having n-conductivity and a region having p-conductivity, thereby forming an np-junction in the interface.

Semiconducting structures comprising multiple n-regions having an n-conductivity and multiple p-regions having a p-conductivity may be provided, so that multiple np-junctions are formed. A higher efficiency and/or voltage may be provided by providing multiple np-junctions.

The semiconducting structure may have a first lattice constant and the first electrode may have a second lattice constant or no lattice constant, i.e. not being crystalline at all, the first and second lattice constants being different, i.e. there is a lattice mismatch between the semiconducting structure and the substrate on which it is grown. For example for an InAs structure, the lattice constant of 6.1 Å is different than for a GaAs substrate with a lattice constant of 5.7 Å. In another example, the lattice of the semiconducting structures is not matched to the substrate, since the substrate does not posses a lattice, i.e. it is not crystalline, e.g. a glass substrate. It is an advantage that semiconducting structures may be provided which are not lattice-matched to the substrate on which they are grown, since a great flexibility is provided in the type of substrate that may be used. For example an inexpensive substrate may be used, such as a silicon substrate, e.g. a glass substrate, a polymer substrate, or other standard substrates. The lattice of the semiconducting structure at the interface to the substrate may adapt itself to the surface of the substrate.

The semiconducting structure may have a band gab in a range appropriate for a specific application. In embodiments may the semiconducting structure have a band gab in the range of 0.25 eV to 2 eV. The specific size of the band gab may be tuned by the effective size of the semiconducting structure. For example by selecting or providing an appropriate size of a region of the semiconducting structure, such as an n-type region or a p-type region of an appropriate size, the energy band of the structure may be shifted with respect to energy bands of a bulk structure of the same material. By properly adjusting proper sizes of the semiconducting structure, a specific band gab may thereby be provided.

The second electrode may be a top electrode. The second electrode may be of a transparent conductor material, such as a TCO. Also a transparent conducting polymer may be used. The second electrode may also be an insulator contacted with a conducting or semiconducting electrode, such as a glass electrode coated with a metal layer or a semiconducting layer, of a conducting polymer material, an insulating polymer coated with a conductor, etc.

The second electrode may be a layered substrate having a first layer and at least a second layer.

The active element may comprise a filler element being at least partly transparent in a second wavelength range. The optical properties of the second wavelength range may be selected within the range as specified for the first wavelength range. The filler material may be glass, silicon mono-oxide, silicon di-oxide, a polymer, or any other suitable material. Typically, the filler material is an electrical insulator.

In an advantageous embodiment, the filler material may be an SU-8 based polymer. The chemical name of SU-8 is glycidyl ether of bisphenol A. SU-8 may be a suitable filler material since it has a high chemical resistance, it is compatible with conventional microfabrication techniques, and it is relatively easy and fast to process.

In a second aspect of the invention, there is provided a method of fabricating an optical device, the method comprising:
providing a first electrode;
providing nucleation centres on the first electrode;
depositing at least a first material so as to form a plurality of semiconducting structures extending in a lengthwise direction from the first electrode.

The method according to the second aspect may be applied for providing a device in accordance with the first aspect of the invention.

The plurality of semiconducting structures may be, or may form part of an active element.

The method may be conducted in connection with molecular beam epitaxy (MBE) or any other method capable of growing micro or nanostructures on a substrate. For example in connection with Metalorganic vapour-phase epitaxy (MOPVE), chemical beam epitaxy (CBE), or similar methods of growing a nanostructure.

Additional steps may be conducted such as a step for depositing a filler material onto the semiconducting structures, a step for the provision of a second electrode, so that the plurality of semiconducting structures may be disposed between and in contact with the second electrode.

A first region of the semiconducting structures may be provided with a first region of a first type of conductivity of either p-type or n-type and wherein at least a second region of the semiconducting structures are provided with a second section of a second conductivity of either p-type or n-type, the first and second regions forming an np-junction.

A first region of the semiconducting structures may be provided by depositing a first material during a growth procedure and wherein the second material is provided by depositing a second material during the growth procedure.

The semiconducting structures may be grown with a first type of conductivity and in later step doped with a material so that a doped region is formed, the doped region being of a 15 second type of conductivity.

The doping may be done by means of a coating step and optionally a heating step.

The doping may be done by injecting dopants into the semiconducting structures, e.g. by means of ion bombardment.

The semiconducting structures may be grown with a first type of conductivity and in later step coated with a material of a second type of conductivity. The interface between the semiconducting structures and the coating is forming the np-junction.

In further aspects, a photovoltaic device, a radiation detector and a light emitting device are provided.

The individual aspects of the present invention may each be combined with any of the other aspects. These and other aspects of the invention will be apparent from the following description with reference to the described embodiments.

### BRIEF DESCRIPTION OF THE FIGURES

Embodiments of the invention will be described, by way of example only, with reference to the drawings, in which

FIG. 1 illustrates a schematic embodiment of a photovoltaic cell;

FIG. 2 is a SEM image showing a plurality of flakes as seen from an inclined view;

FIG. 3 is a SEM image showing a few flakes as seen from a top view;

FIG. 4 is a SEM image showing a single flake together with specific geometric orientations;

FIG. 5 is a SEM image showing a side view of a flake;

FIG. 6 is a TEM image of a top section of a flake together with a close-up TEM image of a section of the flake;

FIG. 7 is a schematic illustration of the growth scenario of the flake growth;

FIGS. 8A to 8C illustrate inclined SEM images of flakes grown at varying growth conditions.

FIGS. 9 to 13 are schematic illustrations of embodiment of flakes having an np-junction;

FIG. 14 illustrates an SEM image of flakes embedded in an SU-8 filler; and

FIG. 15 illustrates a flow diagram of a general procedure of fabricating an optical device.

### DESCRIPTION OF EMBODIMENTS

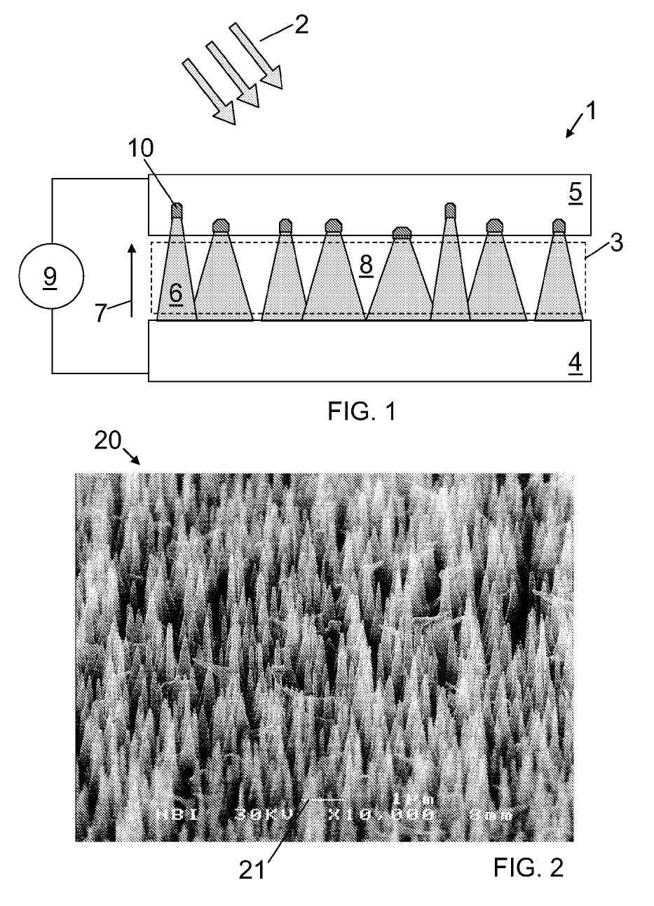

FIG. 1 illustrates a schematic embodiment of an optical device in accordance with the present invention. The illustrated optical device is in the form of a photovoltaic cell 1. In operation, the photovoltaic cell may operate as a solar cell intended to be exposed to radiation 2, such as solar radiation. The radiation is coupled into an active element 3 where electron-hole pairs are created giving rise to an electrical potential 9 which may be exploited for electrical purposes.

The optical device 1 comprises a first electrode or substrate 4 and a second electrode or top electrode 5. Moreover, the device comprises an active element 3 being disposed between the first and second electrodes. In order to couple incoming radiation into the active semiconducting structure, the first or second electrode is at least partly transparent in a first wavelength range. Typically only one of the first or second electrodes is transparent, however both may be transparent.

Moreover, the active element may comprise filler element 8 provided in the regions between the semiconducting structures so as to provide a substantial solid active element.

In an alternative embodiment of a general radiation detector, the optical properties of the system may be provided so that a specific wavelength range is detected. An electrical potential between the two electrodes 4, 5 may be indicative or correlated to a specific intensity of incoming radiation of specific optical characteristics.

In another alternative embodiment, a light emitting device such as a LED is provided. In such an embodiment holes are injected at one of the electrodes and electrons are injected at the other electrode, the electron-hole pair being recombined at the np-junction in a radiative recombination process. The generated radiation is coupled out of the active elements.

The active element comprises a plurality or ensemble of semiconducting structures 6 extending in a lengthwise direction 7 from the first electrode and being in contact with the first and second electrodes. The geometrical structure of the semiconducting structures is typically in the general form or shape of a plate, however in embodiments only a part of the semiconducting structure may be of a general plate form or shape. In embodiments the flakes are grown by means of the Vapour-Liquid-Solid (VLS) process, this process is may also be referred to as the Vapour-Solid-Solid (VSS) process due to uncertainty in the specific growth mechanism at the atomic level. In a VLS-process, nucleation centres in the form of catalytic particles, typically metal particles, e.g. gold particles, are deposited or otherwise provided on the substrate before the growth of the semiconducting structures in initiated. Such particles 10 are positioned at a top of the semiconducting structures. Catalytic particles in the form of a metal or another conductor material may ensure a good electrical contact between the semiconducting structures and the top electrode 5.

Embodiments of the growth process are discussed further below.

FIGS. 2 to 5 show SEM images of InAs flakes grown by MBE on a GaAs-substrate. The InAs flakes are grown on the (100) face of a GaAs-substrate. The InAs flakes were grown with a V/III-BEP-ratio of 5.7 using a beam equivalent pressure (BEP) of 1.2×10⁻⁵ torr for As₄, and a BEP of 2.1×10⁻⁶ torr for In. The substrate was held at a temperature of approximate 420° C. and the growth time was 2 hours.

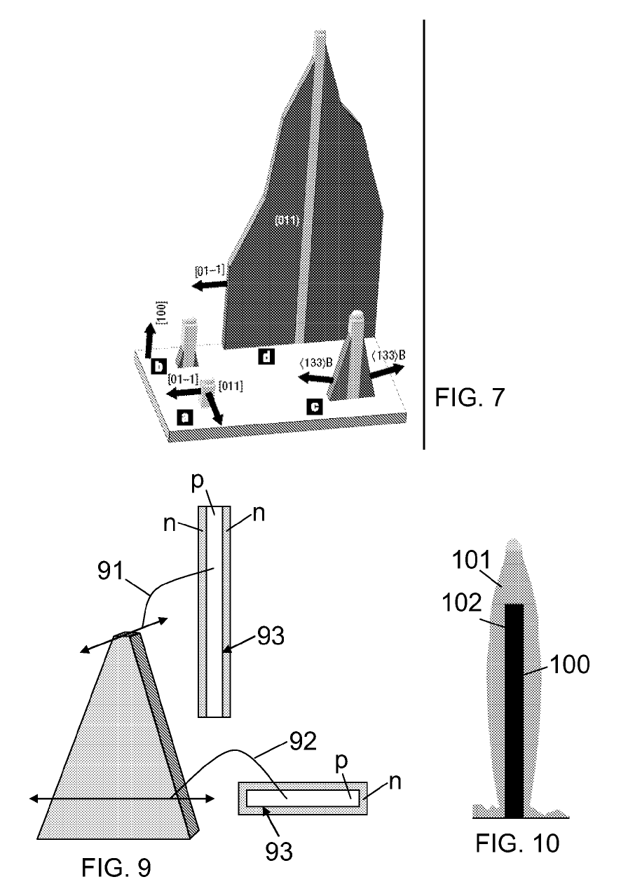

FIG. 2 illustrates a SEM image 20 obtained at 30 KV with a magnification of 10,000. The scale bar 21 indicates the extension of 1 μm. The SEM image 20 shows a plurality of flakes as seen from an inclined view. As can be seen on the image, the majority of the structures are of a general pointed flake shape. However sub-groups of the structures posses deviating shapes. The specific shape is dictated by a number of parameters and many shapes may be similar in overall energy, thus from kinetic considerations alone a single shape may be impossible to provide. However, importantly, a plurality of similar shapes are provided where most, if not all, posses a general plate shape. The shape of the top of the flakes vary, with no single preferred crystal direction, but the sides of the lower part tend to be close to the (0-11) and (01-1) surfaces, as further elaborated upon in connection with FIGS. 5 and 7.

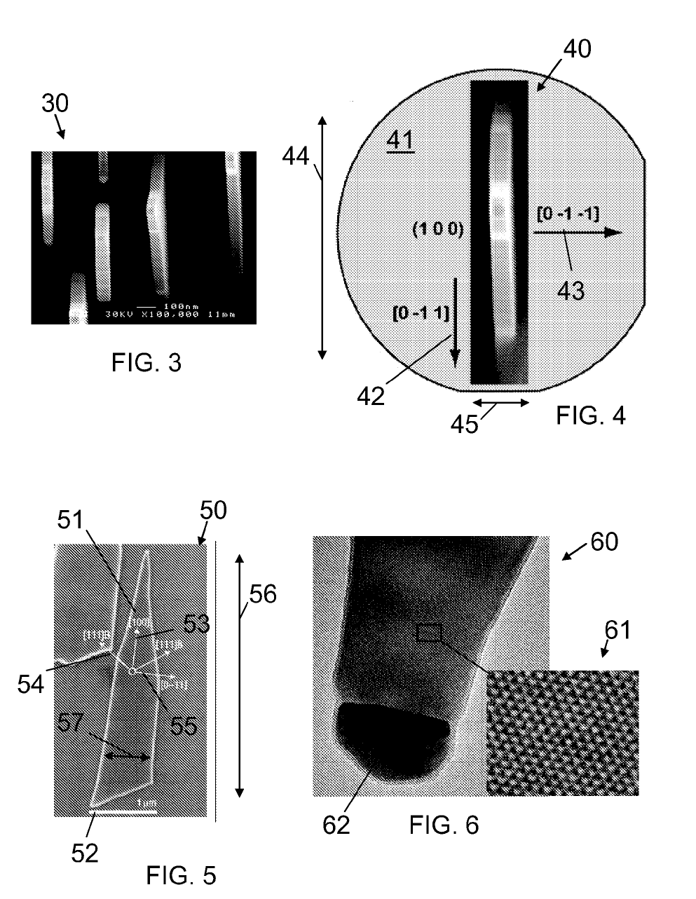

FIG. 3 illustrates a SEM image 30 obtained at 30 KV with a magnification of 100,000. The scale bar indicates the extension of 100 nm. The SEM image 30 shows a few flakes as seen from a top view.

FIG. 4 illustrates a SEM image 40 of a single flake. The flake is shown together with the (100) plane, being the plane of the paper. Also the [0-11] direction 42 and the [0-1-1] direction 43 are shown.

FIG. 5 illustrates a SEM image 50 of a flake 51 that have been removed by ultrasound and deposited on a silicon oxide surface. The scale bar 52 indicates the extension of 1 μm. The flake is shown together with the [100] direction 53, the [111] direction 54 and the [0-11] direction 55.

From the FIGS. 2-5 it is clear that the semiconducting structures have heights 56, the heights extending in the lengthwise direction 7, as well as widths 44 extending along the [0-11] direction and thicknesses 45 extending along the [0-1-1] direction. At a section positioned at the lower half of the semiconducting structure, the position being placed e.g. as indicated on FIG. 5 by reference numeral 57, the width to thickness ratio is approximately 1 μm to 80 nm being 12.5. The shown crystal directions are for the system of InAs grown of the (100) face of GaAs. Specific crystal directions depend on specific systems, thus for different semiconducting structures and/or different substrates, different crystal directions may be relevant. The crystal directions are shown for illustrative reasons so as to characterize the illustrated embodiment, the scope of the invention is not limited to specific crystal directions.

FIG. 6 shows a TEM image 60 of the top section of a flake together with a close-up TEM image 61 of a section of the flake. The specific location of the TEM image does not correspond to the indicated one, the specific location is only provided for illustrative reasons. Also an encapsulated gold catalytic particle 62 is shown. From the close-up TEM image showing atomic resolution, it can be seen that the InAs flake is substantially mono-crystalline with not more than only a few point defects, if any. Moreover, energy dispersive X-ray analysis (EDX) measurements on the flakes reveal a 50/50 distribution between In and As in the flakes. Diffraction analysis of the flakes reveal that the InAs lattice is unstrained, at least for the majority of the flake.

FIG. 7 is a schematic illustration of the growth mechanism of the flake shape as understood by the time of filing of the present document for InAs flake growth on GaAs(100) in MBE with Asₒ as the group V material and In as the group III material. Due to the complex nature of nanoparticle growth, there is some uncertainty related to the growth mechanism. The growth behaviour has been deduced from an investigation of the flake shape as a function of growth time. It is expected that the flake begins with a rod structure having a square cross-section growing in the [100] direction and having the four nonpolar {011} planes as side facets (FIG. 7a). As the growth continues, a small platelet is formed at the intersection between the (100) substrate surface and {011} crystal planes at the base of the rod, but only in the two arsenic-terminated directions (FIG. 7b). This is likely a result of the arsenic incorporation kinetics on (011) and (111)A surfaces. The resulting arsenic-terminated surfaces created on the two sides of the rod crystal are high-energy surfaces with a significantly higher incorporation coefficient under the growth conditions used compared with the low-energy nonpolar {011} surfaces. As a consequence, InAs growth now takes place almost only on these high-energy surfaces, except for the Au-catalysed vapour-solid-solid (VSS) growth. As the growth continues the flakes reaches a triangular shape with surfaces that, judging from the scanning electron microscopy (SEM) images, most likely are {133}B surfaces having an angle of 76.78 relative to the (100) substrate surface (FIG. 7c). With increasing growth times the epitaxial vapour-solid (VS) InAs growth on the high-energy {133}B surfaces causes them to continue upward and outward, thereby increasing the flake width. Average widths at the flake base have been observed to be between 350 nm to 500 nm. These widths are depending upon the specific growth conditions. For longer growth times the height of the flake reaches a point, likely connected with the surface diffusion length of the In, where the growth rate on the lower part of the two {133}B surfaces starts to increase. This results in the {133}B surfaces slowly changing towards becoming the vertical nonpolar {011} surfaces. At the same time the Au-catalysed growth at the top of the flake continues, thereby causing the high-energy B surfaces still to exist at the top of the plate. The final shape of the flake is reached after a few micrometres of vertical growth, and here the top of the flake is formed by the still continuing VSS growth combined with the two arsenic-terminated surfaces connecting the Au—In eutectic particle to the lower sides of the flake, which are close to being the nonpolar {011} surfaces (FIG. 7d). This final flake shape has been observed to exist for growth heights up to at least 15 μm for growths using As₂. The growth times used to grow the flakes range between 30 and 120 minutes.

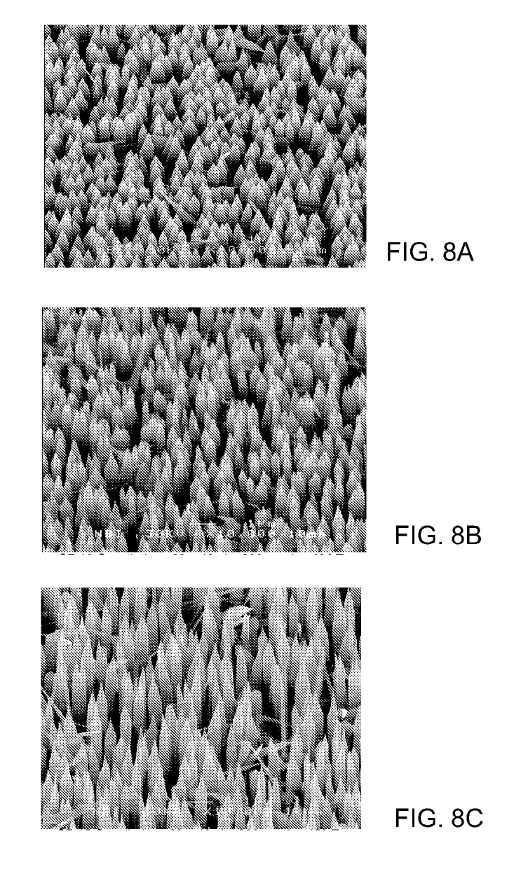

FIGS. 8A to 8C illustrate inclined SEM images of InAs flakes grown by means of MBE on the (100) face of a GaAs-substrate at different V/III-BEP-ratio and different substrate temperature. The V/III-ratio has been changed by changing the BEP of the As₄-beam. The images are obtained at 30 KV with a magnification of 10,000. The scale bar indicates the extension of 1 μm.

The InAs flakes of FIG. 8A were grown with a V/III-BEP-ratio of 4.3 using a beam equivalent pressure (BEP) of 3.6×10⁻⁶ torr for As₄, and a BEP of 8.3×10⁻⁷ torr for In. The substrate was held at a temperature of approximate 420° C. and the growth time was 1.5 hours.

The InAs flakes of FIG. 8B were grown with a V/III-BEP-ratio of 5.4 using a beam equivalent pressure (BEP) of 4.5×10⁻⁶ torr for As₄, and a BEP of 8.4×10⁻⁷ torr for In. The substrate was held at a temperature of approximate 420° C. and the growth time was 1.5 hours.

The InAs flakes of FIG. 8C were grown with a V/III-BEP-ratio of 6.5 using a beam equivalent pressure (BEP) of 5.3×10⁻⁶ torr for As₄, and a BEP of 8.2×10⁻⁷ torr for In. The substrate was held at a temperature of approximate 410° C. and the growth time was 1.5 hours.

The images illustrate that the individual flake structure as well as the overall ensemble properties change with changed growth parameters or conditions. Generally, at lower substrate temperatures and lower V/III-BEP-ratios, the flake density is higher than for higher temperatures and V/III-BEP-ratios. Moreover, also a higher degree of wide flake shapes are observed for lower substrate temperatures and lower V/III-BEP-ratios, than for flakes grown at higher temperatures and V/III-BEP-ratios.

Suitable V/III-BEP-ratios are found between 3.5 and 5.5, and suitable substrate temperatures are found between 350° C. and 450° C. However, it is to be understood that the invention is not limited to these ranges, since appropriate structures may also be found outside these ranges.

The flakes illustrated in FIGS. 2-6, 8, 14 were grown using As₄, but growths Using As₂ is also possible. When using a beam of As₂ the thickness of the flakes was seen to increase with growth time as compared to As₄ growth, moreover for the same amount of deposited Au, the thicknesses of the flakes are observed to be larger for the As₂-grown samples than for those grown using As₄, this agrees with the higher incorporation coefficient of As₂ on {011} surfaces.

FIG. 9 is a schematic illustration of an embodiment of a flake having an np-junction 93. The np-junction is provided by having a semiconducting structure comprising an n-region having an n-conductivity and a p-region having a p-conductivity, the regions forming an np-junction. The placement of the n-region and the p-region is illustrated by cross-sections. A first cross-section as denoted by the reference numeral 91 and a second perpendicular cross-section as denoted by reference numeral 92. A semiconducting structure as generally shown by FIG. 9 may be provided in a number of ways.

In an embodiment, the differences in growth using As₄ and As₂ may be used to grow a flake having a general structure as illustrated in FIG. 9. A schematic illustration of this embodiment is provided in FIG. 10.

FIG. 10 illustrates an embodiment, where the flakes are grown with a first growth stage and at least a second growth stage. In a first growth stage the inner semiconducting structure 100 is grown with a first conductivity (e.g. p-conductivity) using As₄. This results in flakes with a significant larger width than thickness (here seen in a cross-section corresponding to the cross-section denoted 91 in FIG. 9). Once an appropriate size and shape distribution has been obtained, i.e. after a given time of growth, further growth is continued using As₂. In the second growth stage the outer semiconducting structure 101 is grown with a second conductivity (e.g. n-conductivity) using As₂. This results in flakes with a shell of n-conductivity. np-junctions 102 are thereby obtained inside the flakes. For the resulting semiconducting structures the width-to-thickness ratio is smaller than for the width-to-thickness ratio of the inner structures, grown by As₄. However, at least the part of the semiconducting structures constituted by the inner structure (the As₄ grown structure) is of a general plate shape where, at a section positioned at the lower half of the structure, the width is substantially larger than the thickness. That is, at least the inner structure has a flake shape as discussed in connection with the SEM images.

In an embodiment, a p-type semiconducting structure is grown on top of which a donor material is deposited. The system may be heated to a temperature so that the donor material migrates into the shell region or surface region of the p-type semiconducting structure thereby providing donor impurities and changing the conductivity type to n-type. An np-junction is thereby provided. Also multilayer deposition followed by heating may be used to provide an n-type region or shell. For example an annealed multilayer of Ge, Au and Ni may be used to provide an n-type region covering a p-type flake.

In an embodiment the donor material may be deposited by means of spin-on doping.

In an embodiment the donor material may be sputtered into to the shell region of the semiconducting structure. The donor material is thereby provided in the form of donor ions.

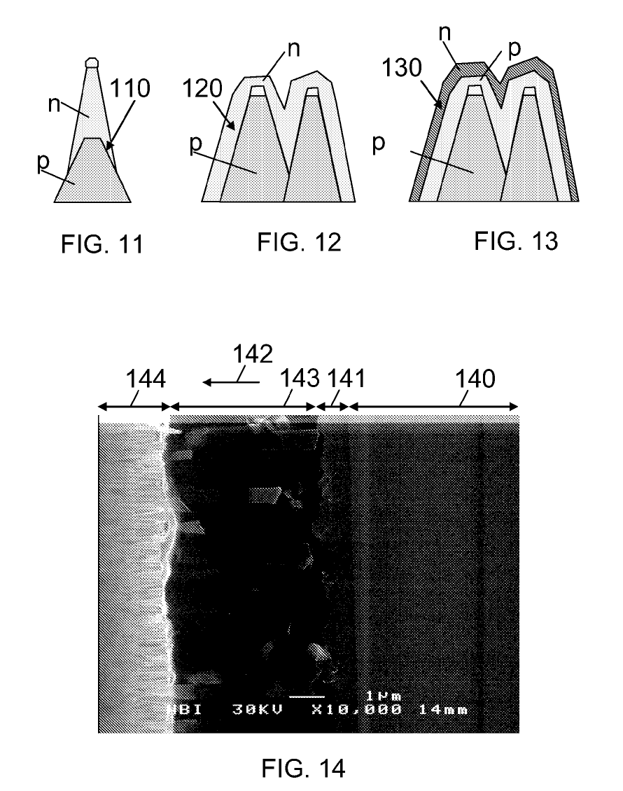

FIG. 11 is a schematic illustration of an embodiment of a flake having an np-junction 110. The np-junction is provided by growing a first part of the semiconducting structure with a p-type material and a second part of the semiconducting structure with an n-type material. This may be obtained by changing the growth material, e.g. in the MBE the material of the beam may be changed during growth. This process may be continued thereby forming multiple n-regions having an n-conductivity and multiple p-regions having a p-conductivity, so that multiple np-junction are formed.

Instead of changing the growth material during growth, the p-type semiconducting structure may be grown in a first step, afterwhich an n-type material is deposited onto the semiconducting structure, a schematic embodiment is illustrated in FIG. 12. Separate structures of different materials are provided so that a semiconducting structure of p-conductivity is abutting a region or coating having an n-conductivity, so that the interface between the semiconducting structures and the region is forming the np-junction 120.

Instead of changing the growth material during growth, the p-type semiconducting structure may be grown in a first step, afterwhich an n-type material is deposited onto the semiconducting structure, a schematic embodiment is illustrated in FIG. 12. Separate structures of different materials are provided so that a semiconducting structure of p-conductivity is abutting a region or coating having an n-conductivity, so that the interface between the semiconducting structures and the region is forming the np-junction 120.

FIG. 13 illustrates an embodiment, where semiconducting structures of p-conductivity are provided and onto which a semiconductor material of the same conductivity is provided. Onto the first layer of semiconductor material of p-conductivity a semiconductor material of different conductivity, or n-conductivity, is provided, so that the semiconducting structure comprises or supports a region having n-conductivity and a region having p-conductivity forming an np-junction 130.

The inner part of the semiconducting structure may in an embodiment be an p-type InAs flake. The first layer may be a p-type GaAs layer and the second layer may be an n-type GaAs.

In the schematic embodiments illustrated in FIGS. 9-13 the np-junction are provided over the entire semiconducting structure. However, part of the semiconducting structure may be covered by a filler material before providing the np-junction, so that only a part of the semiconducting structure is covered by or supporting an np-junction.

Above, reference has been made in the Figures to specific regions of n-conductivity and p-conductivity. It is to be understood that regions of n-conductivity may be interchanged with regions of p-conductivity and vice versa.

FIG. 14 illustrates an SEM image of InAs flakes grown by MBE on a GaAs-substrate where the flakes are embedded in an SU-8 filler. The image is obtained at 30 KV with a magnification of 10,000. The scale bar indicates the extension of 1 μm. The image is obtained in cross-section.

A bulk GaAs is used as the supporting substrate 140, and on top of the GaAs the InAs flakes are provided. In connection with the growth a thin layer 141 of bulk InAs has occurred. The flakes are protruding in the direction marked 142. The flakes are partly embedded in an SU-8 filler 143, and the top of the flakes are protruding out of the filler 144. The flakes protruding out of the filler have been covered with a thin layer of Au. The part of the flakes which are embedded by the SU-8 filler cannot clearly be seen due to the presence of the filler material.

The filler material has been provided onto the flakes be dripping a small drop of liquid SU-8 onto the substrate followed by spinning of the system with 2000 rpm in 55 sec. The system is hardened by baking it on a hotplate at 115° C. in 105 sec.

From inspection of the SEM images no or only very few holes or imperfections of the filler material have been found, revealing a very good penetration of the SU-8 material into the spaces between the flakes.

The semiconducting structures as shown in the Figures are grown in an MBE system. In a specific exemplary embodiment, the growth has been done as described in the following.

A solid source Varian GEN II MBE system with a growth chamber base pressure in the low 10⁻¹¹ torr range was used. The system used As₄ as the group V material and In as the group III material, both materials had an MBE grade purity.

Prior to growing the semiconducting structures, a GaAs (100) substrate in a form ready for epitaxial overgrowth was received from the producer.

The substrate was mounted in a substrate holder and loaded into the MBE system load lock where it was degassed at 200° C. for approximately 2 hours. The pressure in the load lock was then allowed to recover to the 10⁻⁷ torr range and the substrate subsequently transferred to the growth chamber, via a buffer chamber.

In the growth chamber the substrate was constantly exposed to an As₄ flux with a Beam Equivalent Pressure (BEP) of approximately 1.2×10⁻⁵ torr. The substrate was heated to around 560° C. for 10 minutes before a thin layer of Au was deposited onto it. The Au deposition was done by heating a 16 cc crucible to 1350° C. and then opening the shutter in front of it for 150 seconds. In this process between 0.5-2 nm Au was deposited on the substrate surface, the thickness estimate is however somewhat uncertain.

Still in the growth chamber and in an As₄ flux the substrate was kept at the around 560° C. for 10 minutes after Au deposition to allow the Au to form the nanosized growth catalyst particles. After 10 minutes the substrate temperature was lowered to the growth temperature and the growth initiated by opening the In shutter. The growth took up to a few hours after which the In shutter was closed and the substrate temperature was lowered to 200° C. still in an As₄ flux.

When the substrate temperatures reached 200° C. the substrate was removed from the MBE system.

The substrate temperatures mentioned above have been converted from the temperature measured with a thermocouple at the substrate growth position in the MBE system to what, to the best of our knowledge, is the real substrate temperature corrected for the thermocouple error. The substrate temperature measured with the thermocouple in the growth chamber during Au deposition was 640° C. The substrate temperature measured with the thermocouple during flake growth was 470° C.

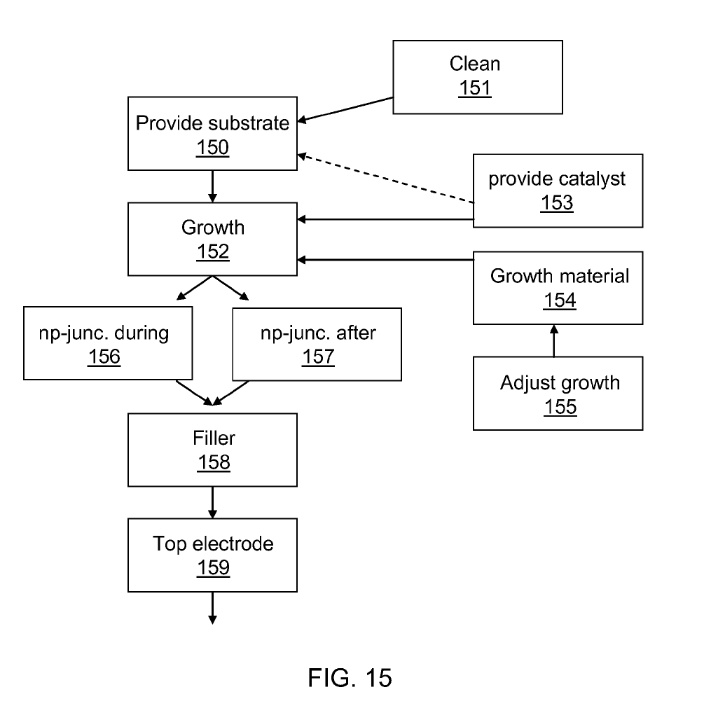

FIG. 15 illustrates a flow diagram of a general procedure of fabricating an optical device in accordance with embodiments of the present invention.

In a first step, a substrate is provided. The substrate may in a prior step be grown, cut and polished, cleaved, etc. The substrate may be provided in a final state so that no additional cleaning is needed, however typically, the substrate needs to be cleaned 151. For example it may be cleaned by means of annealing or degassing, by means of sputter-annealing cycles, by means of exposure to specific gases, e.g. followed by annealing or sputter-annealing cycles, by means of flushing with specific gases, possible while heating the substrate, by means of wet etching, such as etching in HF followed by rinsing in clean water or alcohol and dried in a flow of nitrogen.

As an example, a GaAs (100) substrate may be degassed in a number of steps at a temperature of a few hundred degrees, such as 200° C. in a first background pressure and subsequently at 400° C. in a second, typically lower, background pressure, for a few hours, such as 2 to 4 hours.

The semiconducting structures may next be grown on the substrate 122, e.g. by means of VLS growth.

In the VLS growth mechanism, nucleation centres in the form of catalytic particles are first deposited onto the substrate 153. Typically Au particles are provided, other suitable catalytic particle include but are not limited to Pt, Pd, Ni and Fe. A quantity corresponding to a few nm, such as between 0.1-5 nm may be deposited. The substrate may e.g. be heated for a specific time, such as 5 to 20 minutes, for redistribution, resizing or reshaping of the catalytic particles. Also, the substrate may be maintained at an elevated temperature during deposition.

Typically, the catalytic particles may be provided by vapour deposition of the particles, e.g. from heating a crucible. Alternatively means include, but are not limited to, deposition of colloid particles and nano-imprint lithography techniques. Both colloids and nano-imprint lithography may be done before the sample is transferred into the growth chamber.

The substrate is typically maintained at a specific temperature while growing the semiconducting structures. A typical growth temperature ranges from room temperature to 800° C. For example, InAs semiconducting structures may be grown by exposing the substrate to an As₄ beam and an In beam at a substrate temperature of 400 to 450° C., such as 420° C. However, InAs semiconducting structures may also be grown by exposing the substrate to an As₂ beam and an In beam, however, the substrate temperature and/or V/III ratio or other parameters may be different than for an As₄ beam.

The substrate is exposed to the growth material 154, typically in the form of a beam or vapour, for a period of time, such as from few minutes to several hours. During growth the substrate is exposed to fluxes of relevant materials, the growth material may e.g. be incorporated in a carrier gas. The specific sizes of the different fluxes are adjusted 155, to achieve a specific ratio of the impinging species. As an example, for InAs growth a V/III ratio between 3.5 and 5.5 may be set. Also the specific materials may be adjusted or changed during the growth.

The semiconducting structures are provided with np-junctions, this may be obtained in different ways. In an embodiment, the np-junction is provided during the growth 156 e.g. by controlling and adjusting the composition of the flux, e.g. by introducing a new species at a certain point in time, and possibly shutting off a given other species. In another embodiment, the np-junction is provided after the semiconducting structure have been grown 157, for example by means of doping or deposition of additional layers.

A filler material may in a next step 158 be provided onto the semiconducting structures, and a top electrode 159 may be provided onto the filler material.

In additional steps, the electrodes may be contacted to electronic circuitry, a housing may be provided, etc.

Moreover, additional steps or alternative steps may be provided. For example in an embodiment where the substrate is insulating or insufficiently conducting, a conductor layer may be deposited onto the combined system of semiconductor structures and substrate. After the deposition may an etch step be performed. Etching of the layer on the semiconducting structures will typically be at a higher rate than etching the layer deposited on the substrate. Thus by stopping the etch process when the semiconducting structures have been freed from the deposited material, a layer of the material may still be present at the substrate, thereby providing an electrical contact to the structures.

Although the present invention has been described in connection with the specified embodiments, it should not be construed as being in any way limited to the presented examples. The scope of the present invention is to be interpreted in the light of the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

1-34. (canceled)

35. An optical device comprising:
a first electrode;
a second electrode, the first and/or second electrode being transmissive for radiation in a first wavelength range; and
an active element having an n-p junction disposed between the first and second electrodes, the active element comprising a plurality of semiconducting structures grown in a lengthwise direction out of a planar surface on the first electrode and being in electrical contact with the first and second electrodes;
wherein each semiconducting structure comprises a plate-like portion in which a width of the structure in a first direction across the planar surface is greater than a thickness of the structure in a second direction across the planar surface that is orthogonal to the first direction, and wherein the plate-like portion includes a tapering portion in which the width of the structure decreases as it approaches the second electrode.

36. A device according to claim 35, wherein the planar surface is a face of a crystalline surface and the lengthwise direction is substantially perpendicular to that surface.

37. A device according to claim 36, wherein the crystalline surface is an (1 0 0) face of a crystalline substrate, and the first direction is the [0 −1 1] direction and the second direction is the [0 −1 −1] direction of that substrate.

38. A device according to claim 37, wherein the tapering portion has sloping surfaces facing substantially in the [1 3 3]B direction.

39. A device according to claim 37, wherein the crystalline substrate is the first electrode.

40. A device according to claim 35, wherein the thickness of the semiconducting structure is in the range 5 nm to 500 nm.

41. A device according to claim 35, where the semiconducting structure is substantially crystalline.

42. A device according to claim 35, where the first electrode and/or each semiconducting structure is a group V/III semiconductor, a group VI/II semiconductor, a group IV semiconductor or an alloy thereof.

43. A device according to claim 35, where the first electrode and/or the second electrode is a transparent conductor.

44. A device according to claim 35, where the first electrode and/or the second electrode comprises a layered substrate having two or more layers.

45. A device according to claim 35, where the semiconducting structure has an absorbance in the visual and/or infrared range of at least 70%.

46. A device according to claim 35, wherein the active element comprises an n-region having an n-type conductivity and a p-region having a p-type conductivity, the n-region and the p-region meeting at the n-p junction.

47. A device according to claim 46, wherein the n-region and p-region are both part of the semiconducting structures.

48. A device according to claim 46, wherein the semiconducting structures are one of n-conductivity or p-conductivity and support semiconductor material of the other conductivity to form the n-p junction.

49. A device according to claim 35, wherein each semiconducting structure includes an inner element of a first semiconductor material, the inner element having the plate-like portion and the tapering portion, and a shell element of a second semiconductor material, the shell element being formed over the inner element.

50. A device according to claim 49, wherein the first semiconductor material is p-type InAs, the second semiconductor material is p-type GaAs and the semiconductor material supported by the semiconducting structures is n-type GaAs.

51. A device according to claim 49, wherein the first and second semiconductor materials have different conductivities, whereby the semiconducting structures comprise multiple n-regions having an n-conductivity and multiple p-regions having a p-conductivity, to form multiple n-p junctions.

52. A device according to claim 49, wherein the second semiconductor material is a different compound from the first semiconductor material.

53. A device according to claim 35, where the material of the semiconducting structure at the n-p junction has a band gap in the range of 0.25 eV to 2 eV.

54. A device according to claim 35, where the active element comprises an electrically insulating filler between the semiconductor structures.

55. A device according to claim 54, wherein the filler (8) is an SU-8 based polymer material.

56. A solar cell comprising:
a first electrode;
a second electrode, the first and/or second electrode being transmissive for radiation in a first wavelength range; and
an active element having an n-p junction disposed between the first and second electrodes, the active element comprising a plurality of semiconducting structures grown in a lengthwise direction out of a planar surface on the first electrode and being in electrical contact with the first and second electrodes;
wherein each semiconducting structure comprises a plate-like portion in which a width of the structure in a first direction across the planar surface is greater than a thickness of the structure in a second direction across the planar surface that is orthogonal to the first direction, and wherein the plate-like portion includes a tapering portion in which the width of the structure decreases as it approaches the second electrode.

57. A photovoltaic device comprising:
a first electrode;
a second electrode, the first and/or second electrode being transmissive for radiation in a first wavelength range; and
an active element having an n-p junction disposed between the first and second electrodes, the active element comprising a plurality of semiconducting structures grown in a lengthwise direction out of a planar surface on the first electrode and being in electrical contact with the first and second electrodes;
wherein each semiconducting structure comprises a plate-like portion in which a width of the structure in a first direction across the planar surface is greater than a thickness of the structure in a second direction across the planar surface that is orthogonal to the first direction, and wherein the plate-like portion includes a tapering portion in which the width of the structure decreases as it approaches the second electrode.

58. A light emitting device comprising:
a first electrode;
a second electrode, the first and/or second electrode being transmissive for radiation in a first wavelength range; and
an active element having an n-p junction disposed between the first and second electrodes, the active element comprising a plurality of semiconducting structures grown in a lengthwise direction out of a planar surface on the first electrode and being in electrical contact with the first and second electrodes;
wherein each semiconducting structure comprises a plate-like portion in which a width of the structure in a first direction across the planar surface is greater than a thickness of the structure in a second direction across the planar surface that is orthogonal to the first direction, and wherein the plate-like portion includes a tapering portion in which the width of the structure decreases as it approaches the second electrode.

59. A method of fabricating an optical device, the method comprising:
forming a plurality of nucleation centres on a planar surface on a first electrode;
depositing material to grow a plurality of semiconducting structures at the nucleation centres in a lengthwise direction out of the planar surface on the first electrode; and
forming a second electrode such that the semiconducting structure are disposed between and in electrical contact with the first and second electrodes,
characterised in that:
growing each semiconducting structure includes:
forming a plate-like portion in which a width of the structure in a first direction across the planar surface is greater than a thickness of the structure in a second direction across the planar surface that is orthogonal to the first direction, and
forming a tapering portion of the plate-like portion in which the width of the structure decreases as it approaches the second electrode.

60. A method according to claim 59, wherein the deposited material is crystalline, and growing each semiconducting structure comprises:
a catalysed vapour-liquid-solid (VLS) or vapour-solid-solid (VSS) process in the lengthwise direction at the nucleation centre, and
an epitaxial vapour-solid (VS) process on a pair of surfaces on opposite sides of the nucleation centre, each surface being inclined to the planar surface and extending further in the first direction than in the second direction.

61. A method according to claim 59, comprising depositing an electrically insulating filler material on the semiconductor structures to form a solid active element before forming the second electrode on the active element.

62. A method according to claim 59, wherein depositing material to grow the plurality of semiconducting structures comprises depositing a first semiconductor material to form an inner element, the inner element having the plate-like portion and the tapering portion, and then depositing a second semiconductor material to form a shell element, the shell element being formed over the inner element.

63. A method according to claim 62, wherein the first and second semiconductor materials have different conductivities, whereby the semiconducting structures comprise multiple n-regions having an n-conductivity and multiple p-regions having a p-conductivity, to form multiple n-p junctions.

64. A method according to claim 62, wherein the second semiconductor material is a different compound from the first semiconductor material.

65. A method according to claim 59, wherein the semiconducting structures are one of n-conductivity or p-conductivity and the method includes depositing a support semiconductor material of the other conductivity to form the n-p junction after the semiconducting structures are formed.

66. A method according to claim 59 including, after the semiconducting structures are grown, doping the deposited material to form a doped region in each semiconducting structure.

67. A method according to claim 66, wherein doping comprises either:
coating the semiconducting structure with a dopant material and optionally heating; or injecting dopants into the semiconducting structures.

68. A light emitting device being provided by the device of claim 35.
